(19) United States
(12) Patent Application Publication
(10) Pub. No.: US 2023/0209950 A1
(43) Pub. Date: Jun. 29, 2023

(54) DISPLAY APPARATUS

(71) Applicant: Samsung Display Co., Ltd., Yongin-si (KR)

(72) Inventors: Changsoon Jang, Yongin-si (KR); Inok Kim, Yongin-si (KR); Chansu Kim, Yongin-si (KR); Keunchan Oh, Yongin-si (KR); Gakseok Lee, Yongin-si (KR); Sanghun Lee, Yongin-si (KR); Soyun Lee, Yongin-si (KR); Jieun Jang, Yongin-si (KR)

(21) Appl. No.: 17/948,941

(22) Filed: Sep. 20, 2022

(30) Foreign Application Priority Data
Dec. 23, 2021 (KR) 10-2021-0186586

(51) Int. Cl. H01L 27/32

(52) U.S. Cl. CPC H01L 27/3218; H01L 27/322

(57) ABSTRACT

A display apparatus including a first sub-pixel, a second sub-pixel, and a third sub-pixel respectively representing different colors is provided. The apparatus includes an upper substrate, a functional layer disposed over the upper substrate and including a first quantum-dot layer and a second quantum-dot layer, and a color filter layer between the upper substrate and the functional layer and including a first color filter, a second color filter, and a third color filter. The first color filter corresponds to the first sub-pixel, the second color filter corresponds to the second sub-pixel, and the third color filter corresponds to the third sub-pixel. The first sub-pixel is a green sub-pixel, and a full width at half maximum of a transmission spectrum of the first color filter is in a range of about 45 nm to about 49 nm.

### CROSS-REFERENCE TO RELATED APPLICATION

This application claims priority to and the benefit of Korean Patent Application No. 10-2021-0186586, filed on Dec. 23, 2021, in the Korean Intellectual Property Office, the entire content of which is hereby incorporated by reference herein.

### BACKGROUND

### 1. Field

One or more embodiments of the present disclosure relate to a display apparatus.

### 2. Description of the Related Art

With the development of electronic apparatuses such as mobile phones, large-scale televisions, and/or the like, various suitable types (kinds) of display apparatuses applicable thereto are under development. As an example, a display apparatus widely used in the market includes a liquid crystal display apparatus having a backlight unit, and an organic light-emitting display apparatus that emits light of different colors for each color region. Recently, a display apparatus having a quantum dot-color conversion layer (QD-CCL) has been developed. A quantum dot is excited by incident light and emits light in a wavelength greater than the wavelength of the incident light. For the incident light, light in a low-wavelength band is primarily used.

Recently, as the purpose of a display apparatus is diversified, various suitable designs to improve the quality of the display apparatus have been sought. For example, as the development of high resolution display apparatuses proceeds, research to improve the color reproduction of the display apparatuses is also actively progressing.

### SUMMARY

One or more embodiments include a display apparatus with a low-reflection characteristic and a high color reproduction characteristic. However, such a technical problem/objective is an example, and the disclosure is not limited thereto.

Additional aspects of one ore embodiments of the present disclosure will be set forth in part in the description which follows and, in part, will be apparent from the description, or may be learned by practice of the presented embodiments of the disclosure.

According to one or more embodiments, a display apparatus may include a first sub-pixel, a second sub-pixel, and a third sub-pixel respectively representing different colors, an upper substrate, a functional layer including a first quantum-dot layer and a second quantum-dot layer, wherein the first quantum-dot layer on the upper substrate may correspond to an emission area of the first sub-pixel, and the second quantum-dot layer may correspond to an emission area of the second sub-pixel, and a color filter layer between the upper substrate and the functional layer and including a first color filter, a second color filter, and a third color filter, wherein the first color filter may correspond to the first sub-pixel, the second color filter may correspond to the second sub-pixel, and the third color filter may correspond to the third sub-pixel, wherein the first sub-pixel may be a green sub-pixel, and a full width at half maximum (FWHM) of a transmission spectrum of the first color filter is in a range of about 45 nm to about 49 nm.

A peak wavelength of the transmission spectrum of the first color filter may be in a range of about 530 nm to about 534 nm.

A transmittance in a wavelength band of about 380 nm to about 480 nm of the transmission spectrum of the first color filter may be less than 1%.

A transmittance in a wavelength band of about 600 nm to about 680 nm of the transmission spectrum of the first color filter may be less than 1%.

The first color filter may include a first pigment which is green, and a second pigment which is yellow, wherein a weight ratio of the first pigment to the second pigment may be about 86:14 to about 94:6.

The first pigment may be a green pigment, and may include at least one of C.I. Pigment Green 7, C.I. Pigment Green 36, C.I. Pigment Green 58, and C.I. Pigment Green 69.

The second pigment may be a yellow pigment, and may include at least one selected from C.I. Pigment Yellow 129, C.I. Pigment Yellow 138, C.I. Pigment Yellow 139, C.I. Pigment Yellow 185, and C.I. Pigment Yellow 231.

A thickness of the first color filter may be in a range of about 2 μm to about 4 μm.

Content of a total pigment included in the first color filter may be about 4 wt % to about 12 wt % based on solid content.

Each of the first sub-pixel, the second sub-pixel, and the third sub-pixel may include a light-emitting diode, and all of the light-emitting diodes may emit blue light.

A color reproduction rate according to a BT2020 standard may be 90% or more.

According to one or more embodiments, a display apparatus may include a lower substrate, a first sub-pixel, a second sub-pixel, and a third sub-pixel each including a light-emitting diode which is over the lower substrate and emits blue light, an upper substrate over the lower substrate with the light-emitting diode therebetween, a functional layer over a surface of the upper substrate facing the lower substrate, wherein the functional layer may include a first quantum-dot layer, a second quantum-dot layer, and a transmission layer, wherein the first quantum-dot layer may correspond to the first sub-pixel, the second quantum-dot layer may correspond to the second sub-pixel, and the transmission layer may correspond to the third sub-pixel, and a color filter layer between the upper substrate and the functional layer and including a first color filter, a second color filter, and a third color filter, wherein the first color filter may correspond to the first sub-pixel, the second color filter may correspond to the second sub-pixel, and the third color filter may correspond to the third sub-pixel, wherein the first sub-pixel may be a green sub-pixel, and the first color filter may include a first pigment which is green, and a second pigment which is yellow, and a weight ratio of the first pigment to the second pigment is about 86:14 to about 94:6.

The first pigment may be a green pigment, and may include at least one of C.I. Pigment Green 7, C.I. Pigment Green 36, C.I. Pigment Green 58, and C.I. Pigment Green 69.

The second pigment may be a yellow pigment, and may include at least one C.I. Pigment Yellow 129, C.I. Pigment Yellow 138, C.I. Pigment Yellow 139, C.I. Pigment Yellow 185 and C.I. Pigment Yellow 231.

A thickness of the first color filter may be in a range of about 2 μm to about 4 μm.

Content of a total pigment included in the first color filter may be about 4 wt % to about 12 wt % based on solid content.

An FWHM of a transmission spectrum of the first color filter may be about 45 nm to about 49 nm.

A peak wavelength of a transmission spectrum of the first color filter may be in a range of about 530 nm to about 534 nm.

A transmittance in a wavelength band of about 380 nm to about 480 nm of a transmission spectrum of the first color filter may be less than 1%.

A transmittance in a wavelength band of about 600 nm to about 680 nm of a transmission spectrum of the first color filter may be less than 1%.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a schematic perspective view of a display apparatus according to an embodiment;

FIG. 2 is a schematic cross-sectional view of a display apparatus according to an embodiment;

FIG. 3 is a view of respective optical layers of a functional layer of FIG. 2;

FIG. 4 is a schematic view showing a reflection spectrum of a first quantum-dot layer according to an embodiment;

FIG. 5 is a schematic graph showing a spectrum of light emitted from a first light-emitting diode of a display apparatus and passing through a first color filter according to an embodiment, and a transmission spectrum of a first color filter according to an embodiment and a comparative example;

FIG. 6 is a schematic graph showing a transmission spectrum of the first color filter according to an embodiment;

FIG. 7 is a schematic graph showing reflectance of the display apparatus including the first color filter according to an embodiment;

FIG. 8 is a graph showing a relationship between a full width at half maximum of a transmission spectrum of the first color filter, reflectance, and a color reproduction rate of the display apparatus according to an embodiment;

FIG. 9 is a schematic graph showing a transmission spectrum of first to third color filters according to an embodiment; and

FIG. 10 is a schematic cross-sectional view of the display apparatus according to an embodiment.

### DETAILED DESCRIPTION

Reference will now be made in more detail to embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, the embodiments are merely described below, by referring to the drawings, to explain aspects of the present disclosure. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present disclosure allows for various suitable changes and numerous embodiments, certain embodiments will be illustrated in the drawings and described in the written description. Effects and features of the disclosure, and methods for achieving them will be clarified with reference to embodiments described below in more detail with reference to the drawings. However, the disclosure is not limited to the following embodiments and may be embodied in various forms.

While such terms as “first” and “second” may be used to describe various components, such components must not be limited to the above terms. The above terms are used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

It will be further understood that, when a layer, region, or component is referred to as being “on” another layer, region, or component, it can be directly or indirectly on the other layer, region, or component. That is, for example, intervening layers, regions, or components may be present.

Sizes of elements in the drawings may be exaggerated or reduced for convenience of explanation. For example, because sizes and thicknesses of elements in the drawings may be arbitrarily illustrated for convenience of explanation, the disclosure is not limited thereto.

In the present disclosure, “A and/or B” means A or B, or A and B. In the present disclosure, “at least one of A and B” means A or B, or A and B.

As used herein, when a wiring is referred to as “extending in a first direction or a second direction,” it means that the wiring not only extends in a straight line shape but also extends in a zigzag or in a curve in the first direction or the second direction.

As used herein, “on a plan view” means that an objective portion is viewed from above, and “on a cross-sectional view” means that a cross-section of an objective portion taken vertically is viewed from a lateral side. As used herein, “overlapping” includes overlapping “in a plan view” and “in a cross-sectional view.”

Hereinafter, embodiments of the present disclosure are described in more detail with reference to the accompanying drawings. When description is made with reference to the drawings, like reference numerals are used for like or corresponding elements.

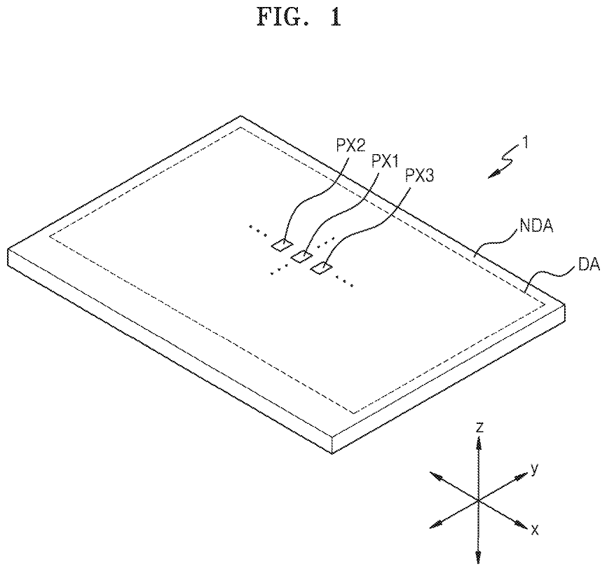

FIG. 1 is a schematic perspective view of a display apparatus 1 according to an embodiment.

Referring to FIG. 1, the display apparatus 1 may include a display area DA and a non-display area NDA, wherein the display area DA is configured to display images, and the non-display area NDA is configured not to display images. The display apparatus 1 may be configured to display images through an array of a plurality of sub-pixels arranged two-dimensionally in an x-y plane in the display area DA. Respective sub-pixels may emit light of different colors, and each sub-pixel may be, for example, one of a green sub-pixel, a red sub-pixel, and a blue sub-pixel.

In an embodiment, a plurality of sub-pixels include a first sub-pixel PX1, a second sub-pixel PX2, and a third sub-pixel PX3. Hereinafter, for convenience of description, the embodiment in which the first sub-pixel PX1 is a green sub-pixel, the second sub-pixel PX2 is a red sub-pixel, and the third sub-pixel PX3 is a blue sub-pixel is described.

The first sub-pixel PX1, the second sub-pixel PX2, and the third sub-pixel PX3 are respectively regions that may emit green light Lg, red light Lr, and blue light Lb. The display apparatus 1 may display images by using light emitted from the sub-pixels.

The non-display area NDA is a region that does not display images and may surround the display area DA entirely. A driver or a main voltage line configured to provide electric signals or power to pixel circuits may be arranged in the non-display area NDA. A pad may be arranged in the non-display area NDA, wherein the pad is a region to which electronic elements or a printed circuit board may be electrically connected.

As shown in FIG. 1, the display area DA may have a polygonal shape including a quadrangular shape. As an example, the display area DA may have a rectangular shape in which a horizontal length thereof is greater than a vertical length, a rectangular shape in which a horizontal length thereof is less than a vertical length, or a square shape. In another embodiment, the display area DA may have a circular shape, an elliptical shape, or a polygonal shape such as a triangle or a pentagon. In addition, though FIG. 1 shows a flat display apparatus having a flat shape, the display apparatus 1 may be implemented in various shapes such as flexible, foldable, and rollable display apparatuses.

In an embodiment, the display apparatus 1 may be an organic light-emitting display apparatus. In another embodiment, the display apparatus 1 may be an inorganic light-emitting display apparatus or a quantum dot light-emitting display apparatus. As an example, an emission layer of a display element of a display apparatus may include an organic material, an inorganic material, quantum dots, an organic material and quantum dots, inorganic material and quantum dots, and/or an organic material, an inorganic material, and quantum dots. Hereinafter, for convenience of description, the embodiment in which the display apparatus 1 is an organic light-emitting display apparatus is primarily described in more detail.

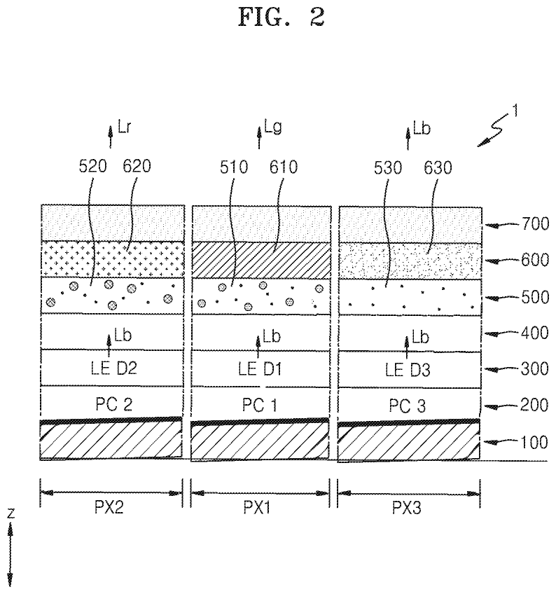

FIG. 2 is a schematic perspective view of the display apparatus 1 according to an embodiment.

Referring to FIG. 2, the display apparatus 1 may include a circuit layer 200 on a lower substrate 100. The circuit layer 200 may include first to third sub-pixel circuits PC1, PC2, and PC3. The first to third sub-pixel circuits PC1, PC2, and PC3 may each include a thin-film transistor and/or a capacitor. The first to third sub-pixel circuits PC1, PC2, and PC3 may be electrically connected to first to third light-emitting diodes LED1, LED2, and LED3, respectively.

The first to third light-emitting diodes LED1, LED2, and LED3 may each include an organic light-emitting diode including an organic material. In another embodiment, the first to third light-emitting diodes LED1, LED2, and LED3 may each include an inorganic light-emitting diode including an inorganic material. The inorganic light-emitting diode may include a PN junction diode including inorganic material semiconductor-based materials. When a forward voltage is applied to a PN-junction diode, holes and electrons are injected and energy created by recombination of the holes and the electrons is converted to light energy, and thus, light of a preset color may be emitted. The inorganic light-emitting diode may have a width of several micrometers to hundreds of micrometers, or several nanometers to hundreds of nanometers. In an embodiment, the light-emitting diode LED may be a light-emitting diode including quantum dots. As described above, the emission layer of the light-emitting diode LED may include an organic material, an inorganic material, quantum dots, an organic material and quantum dots, and/or inorganic material and quantum dots.

The first to third light-emitting diodes LED1, LED2, and LED3 may emit light of the same color. As an example, light (e.g., blue light Lb) emitted from the first to third light-emitting diodes LED1, LED2, and LED3 may pass through a functional layer 500 through an encapsulation layer 400 on a light-emitting diode layer 300. However, the embodiment is not limited thereto. In another embodiment, the first to third light-emitting diodes LED1, LED2, and LED3 may emit light of different colors.

The functional layer 500 may include optical layers configured to convert the color of light (e.g., blue light Lb) emitted from the light-emitting diode layer 300, or configured to transmit the light without converting the color of light. As an example, the functional layer 500 may include quantum dots and a transmission layer, wherein the quantum dots convert light (e.g., blue light Lb) emitted from the light-emitting diode layer 300 to light of a different color, and the transmission layer transmits light (e.g., blue light Lb) emitted from the light-emitting diode layer 300 without converting a color thereof. The functional layer 500 may include a first quantum-dot layer 510 corresponding to the first sub-pixel PX1, a second quantum-dot layer 520 corresponding to the second sub-pixel PX2, and a transmission layer 530 corresponding to the third sub-pixel PX3. The first quantum-dot layer 510 may convert blue light Lb to green light Lg, and the second quantum-dot layer 520 may convert blue light Lb to red light Lr. The transmission layer 530 may transmit blue light Lb without conversion.

A color filter layer 600 may be on the functional layer 500. The color filter layer 600 may include first to third color filters 610, 620, and 630 of different colors. In an embodiment, the first color filter 610 may be a green color filter, the second color filter 620 may be a red color filter, and the third color filter 630 may be a blue color filter.

Light that is color-converted or transmitted by the functional layer 500 may be improved (increased) in color purity thereof while respectively passing through the first to third color filters 610, 620, and 630. In addition, the color filter layer 600 may prevent or reduce reflection of external light (e.g., light incident to the display apparatus 1 from the outside of the display apparatus 1) and may prevent or reduce viewing of reflected light by a user.

An upper substrate 700 may be on the color filter layer 600. The upper substrate 700 may include glass or a light-transmissive organic material. As an example, the upper substrate 700 may include a light-transmissive organic material such as an acryl-based resin.

In an embodiment, after the color filter layer 600 and the functional layer 500 are formed on the upper substrate 700, the functional layer 500 may be integrated to face the encapsulation layer 400.

In another embodiment, after the functional layer 500 and the color filter layer 600 are sequentially formed on the encapsulation layer 400, the upper substrate 700 may be directly coated and hardened on the color filter layer 600. In an embodiment, another optical film, for example, an anti-reflection (AR) film and/or the like, may be on the upper substrate 700.

The display apparatus 1 having the above structure may include electronic apparatuses that may display moving images or still images such as televisions, advertisement boards, screens for a theater, monitors, tablet personal computers, and/or the like.

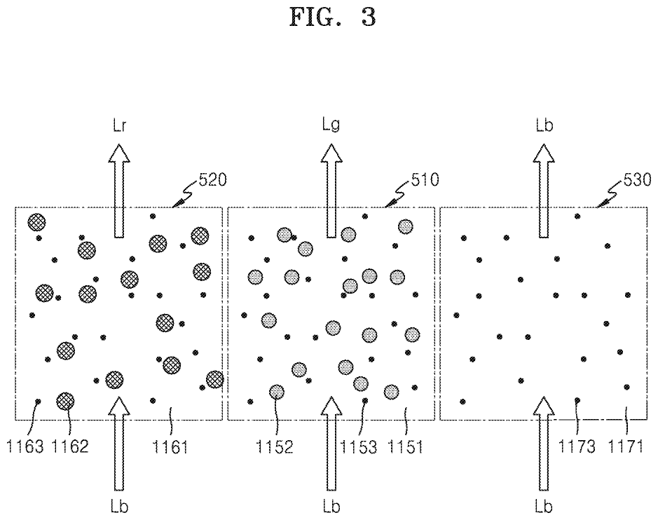

FIG. 3 is a view of respective optical layers of the functional layer of FIG. 2.

Referring to FIG. 3, the first quantum-dot layer 510 may convert blue light Lb incident thereto to green light Lg. As shown in FIG. 3, the first quantum-dot layer 510 may include a first photosensitive polymer 1151, first quantum dots 1152 dispersed in the first photosensitive polymer 1151, and first scattering particles 1153.

The first quantum dots 1152 may be excited by blue light Lb and may emit green light Lg isotropically, wherein the green light Lg has a greater wavelength than the wavelength of the blue light Lb. The first photosensitive polymer 1151 may be an organic material having light transmittance. The first scattering particles 1153 may increase a color-converting efficiency by scattering blue light Lb not absorbed by the first quantum dots 1152 and allowing more first quantum dots 1152 to be excited. The first scattering particles 1153 may be, for example, titanium oxide (TiO₂), metal particles, and/or the like. The first quantum dots 1152 may be one of a Group II-Group VI compound, a Group III-Group V compound, a Group IV-Group VI compound, a Group IV element, a Group IV compound, and one or more combinations thereof.

The second quantum-dot layer 520 may convert blue light Lb incident thereto to red light Lr. As shown in FIG. 3, the second quantum-dot layer 520 may include a second photosensitive polymer 1161, second quantum dots 1162 dispersed in the second photosensitive polymer 1161, and second scattering particles 1163.

The second quantum dots 1162 may be excited by blue light Lb and may emit red light Lr isotropically, wherein the red light Lr has a greater wavelength than the wavelength of the blue light Lb. The second photosensitive polymer 1161 may be an organic material having light transmittance.

The second scattering particles 1163 may increase a color-converting efficiency by scattering blue light Lb not absorbed by the second quantum dots 1162 and allowing more second quantum dots 1162 to be excited. The second scattering particles 1163 may be, for example, titanium oxide (TiO₂), metal particles, and/or the like. The second quantum dots 1162 may be one of a Group II-Group VI compound, a Group III-Group V compound, a Group IV-Group VI compound, a Group IV element, a Group IV compound, and one or more combinations thereof.

In an embodiment, the first quantum dots 1152 may include the same material as that of the second quantum dots 1162. In this embodiment, the average size of the second quantum dots 1162 may be greater than the average size of the first quantum dots 1152.

The transmission layer 530 may transmit blue light Lb without converting the blue light Lb incident to the transmission layer 530. As shown in FIG. 3, the transmission layer 530 may include a third photosensitive polymer 1171 in which third scattering particles 1173 are dispersed. The third photosensitive polymer 1171 may include, for example, an organic material having a light transmittance such as a silicon resin, epoxy resin, and/or the like, and include the same material as that of the first photosensitive polymer 1151 and the second photosensitive polymer 1161. The third scattering particles 1173 may scatter and emit blue light Lb and include the same material as those of the first and second scattering particles 1153 and 1163.

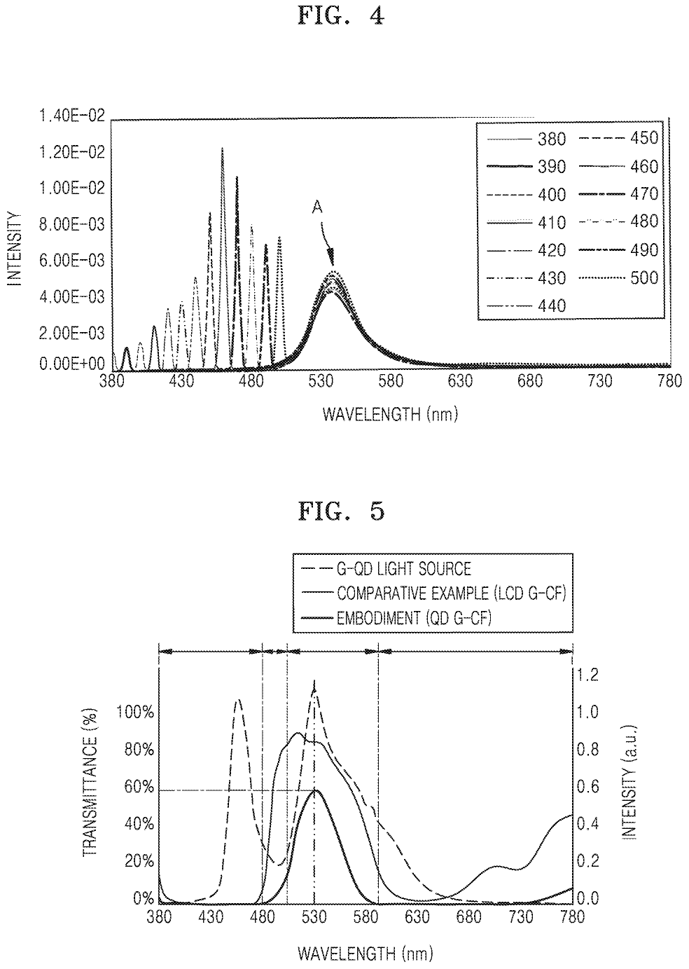

FIG. 4 is a schematic view showing a reflection spectrum of the first quantum-dot layer according to an embodiment.

External light incident to the display apparatus 1 may be reflected by the upper substrate, the inner interface, and/or the like of the display apparatus 1. The display apparatus 1 according to an embodiment includes the first and second quantum-dot layers 510 and 520 that may convert light incident thereto. Accordingly, when a portion of external light reaches the first and second quantum-dot layers 510 and 520, a portion of the light that reaches the first and second quantum-dot layers 510 and 520 may excite the first and second quantum-dot layers 510 and 520 and be converted to light in a different wavelength band and reflected.

As an example, as shown in FIG. 4, in the embodiment in which incident light in a single wavelength band of about 380 nm to about 500 nm reaches the first quantum-dot layer 510, a portion of the light may excite the first quantum dots 1152 and be reflected as light (e.g., a portion A denoted by an arrow in FIG. 4) in a green wavelength band. For example, reflectance in the green wavelength band may increase, which may influence the brightness and/or the like of the display apparatus 1. Accordingly, reflectance needs to be reduced by blocking light in a wavelength band contributing to reflection of light emission of the quantum-dot layer.

The display apparatus 1 according to an embodiment may not include (e.g., may exclude) a polarizing plate and may reduce reflectance by adjusting the transmission spectrum of the first to third color filters 610, 620, and 630 respectively corresponding to the first to third sub-pixels PX1, PX2, and PX3.

As a comparative example, the display apparatus may include a polarizing plate collectively disposed on the plurality of sub-pixels to reduce reflectance. However, as described above, because diffused reflectance increases due to reflection of light emission of the quantum-dot layer, a reflection wavelength may be different for each sub-pixel. Accordingly, a reflectance improvement effect of the display apparatus using the polarizing plate may be insignificant. Furthermore, a transmission efficiency of light emitted from each sub-pixel may be reduced due to the polarizing plate.

The display apparatus 1 according to an embodiment may control the reflectance by selectively adjusting the transmission spectrum of the first to third color filters 610, 620, and 630 respectively corresponding to the first to third sub-pixels PX1, PX2, and PX3. Accordingly, compared to the embodiment in which the polarizing plate is provided, the reflectance of the display apparatus 1 may be reduced even more, and a transmission efficiency of light emitted from the sub-pixels, for example, the first to third sub-pixels PX1, PX2, and PX3, may be also improved (increased).

Hereinafter, light transmission characteristics of the first to third color filters 610, 620, and 630 respectively corresponding to the first to third sub-pixels PX1, PX2, and PX3, are described. Among the characteristics, a light transmission characteristic of the first color filter 610, which corresponds to the first sub-pixel PX1 and which is a green color filter according to an embodiment, is described with reference to FIGS. 5 to 8.

FIG. 5 is a schematic graph showing a spectrum of light emitted from a first light-emitting diode of a display apparatus and passing through a first quantum-dot layer according to an embodiment, and a transmission spectrum of a first color filter according to an embodiment and a comparative example.

In FIG. 5, the spectrum of light emitted from the first light-emitting diode LED1 and passing through the first quantum-dot layer 510 corresponds to y coordinates (the intensity of light) on the right side. In addition, the transmission spectrum of the first color filter 610 according to an embodiment and a transmission spectrum of the first color filter according to a comparative example correspond to y coordinates (a transmittance) on the left side. Here, the first color filter according to a comparative example corresponds to a first color filter according to the related art applicable to a liquid crystal display (LCD) not including a quantum-dot layer.

Referring to FIG. 5, in a transmission spectrum of the first color filter 610 according to an embodiment, a transmittance in a wavelength contributing to reflection of light emission of the first quantum-dot layer 510 may be relatively low compared to a transmission spectrum of the first color filter according to a comparative example. As an example, the transmission spectrum of the first color filter 610 according to an embodiment may have a low transmittance in a wavelength band of about 480 nm to about 515 nm. As shown in FIG. 5, because, in the wavelength band of about 480 nm to about 515 nm, the intensity of light emitted from the first light-emitting diode LED1 and the first quantum-dot layer 510 is relatively low, the contribution of emitted green light Lg to the transmittance may be low. In contrast, in the embodiment in which external light in the above wavelength band reaches the first quantum-dot layer 510, reflection of light emission of the first quantum-dot layer 510 described above with reference to FIG. 4 may be caused. Accordingly, because the spectrum of the first color filter 610 according to an embodiment has a relatively low transmittance in the wavelength band of about 480 nm to about 515 nm, the reflectance of the display apparatus 1 may be reduced even more.

In addition, the transmission spectrum of the first color filter 610 according to an embodiment may have a reduced maximum transmittance but have a smaller full width at half maximum (FWHM) of the spectrum in the wavelength band of about 515 nm to about 600 nm, compared to the transmission spectrum of a first color filer according to a comparative example.

Here, the FWHM denotes a width between points corresponding to ½ of a maximum value of a spectrum representing distribution having a bell shaped curve. For example, in the embodiment of a spectrum representing wavelength dependency such as a transmittance and/or the like, an FWHM denotes a wavelength width.

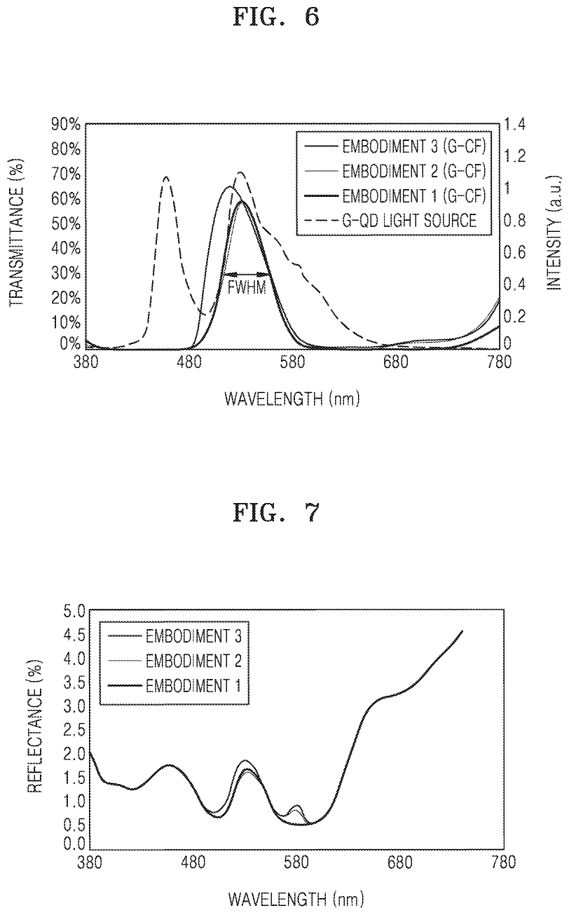

Because the wavelength band of about 515 nm to about 600 nm is the original wavelength band of green light Lg, the first color filter 610 may be designed to have a high transmittance in the relevant band. In addition, as described below with reference to FIGS. 6 to 8, the display apparatus may have excellent or suitable color characteristics, for example, a high color reproduction rate and a low reflectance by adjusting the FWHM of the transmission spectrum of the first color filter 610.

Because, in the display apparatus 1 according to an embodiment, the FWHM of the spectrum is reduced in the wavelength band of about 515 nm to about 600 nm compared to the first color filter according to a comparative example, a color reproduction rate may increase and reflectance may be reduced. Light passing through the first color filter 610 may be green light Lg having high purity.

In addition, a peak wavelength of the transmission spectrum of the first color filter 610 according to an embodiment may be substantially similar to or may coincide with a peak wavelength of the spectrum of light emitted from the first light-emitting diode LED1 and the first quantum-dot layer 510. A peak wavelength of the transmission spectrum of the first color filter 610 may be in a range of about 530 nm to about 534 nm. As an example, a peak wavelength of the transmission spectrum of the first color filter 610 may be about 532 nm. Because the first color filter 610 has a peak wavelength that is substantially similar to or coincides with a peak wavelength of the spectrum of light emitted from the first light-emitting diode LED1 and the first quantum-dot layer 510, a transmission efficiency of green light Lg may be maximized (optimized).

A transmission spectrum of the first color filter 610 according to an embodiment may have a low light transmittance in blue and red wavelength bands. In an embodiment, the transmission spectrum of the first color filter 610 may have a transmittance of less than 1% in a wavelength band of about 380 nm to about 480 nm. In addition, in another embodiment, the transmission spectrum of the first color filter 610 may have a transmittance of less than 1% in a wavelength band of about 600 nm to about 680 nm. A wavelength band of about 380 nm to about 480 nm may be included in the wavelength band of blue light, and a wavelength band of about 600 nm to about 680 nm may be included in the wavelength band of red light. The first color filter 610 according to an embodiment may increase color purity of green light Lg and reduce reflectance by absorbing and nearly not transmitting light in the wavelength band of about 380 nm to about 480 nm or the wavelength band of about 600 nm to about 680 nm.

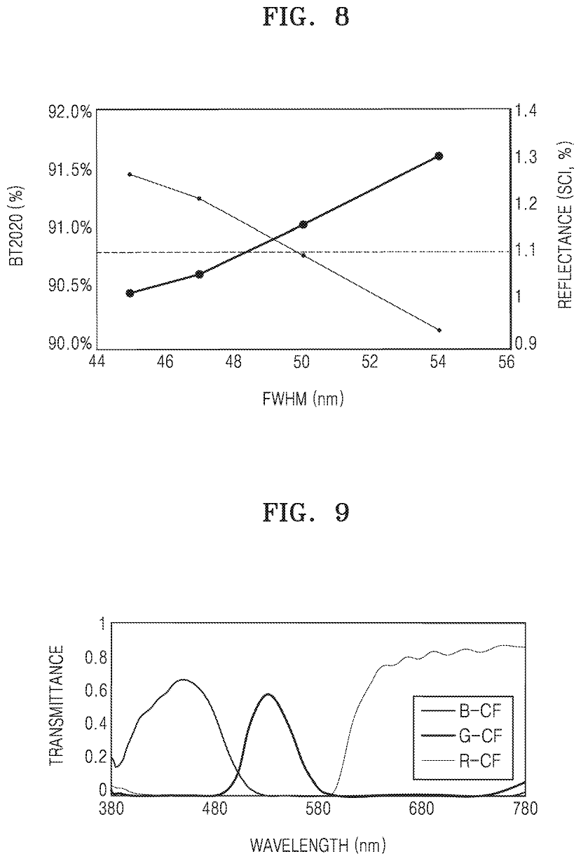

FIG. 6 is a schematic graph showing a transmission spectrum of the first color 610 filter according to an embodiment, and FIG. 7 is a schematic graph showing reflectance of the display apparatus 1 including the first color filter 610 according to an embodiment. FIG. 8 is a graph showing a relationship between an FWHM of a transmission spectrum of the first color filter 610, reflectance, and a color reproduction rate of the display apparatus 1 according to an embodiment.

Referring to FIGS. 6 and 7, Embodiments 1 to 3 correspond to the first color filters 610 with different FWHMs of a transmission spectrum. As shown in FIG. 7, as the FWHM of the transmission spectrum of the first color filter 610 is reduced, reflectance in a green wavelength band may be reduced.

Referring to FIGS. 6 to 8, as the FWHM of the transmission spectrum of the first color filter 610 according to an embodiment is reduced, the reflectance of the display apparatus 1 may be reduced, and concurrently (e.g., simultaneously), a color reproduction rate may increase. However, because an FWHM is reduced, the reduced FWHM may influence a transmission efficiency of green light. Accordingly, an FWHM may be set such that a light transmittance efficiency, reflectance, and a color reproduction rate are optimized. In an embodiment, an FWHM of the transmission spectrum of the first color filter 610 may be in a range of about 45 nm to about 49 nm. As an example, an FWHM of the transmission spectrum of the first color filter 610 may be about 47 nm.

In an embodiment, a maximum transmittance of the transmission spectrum of the first color filter 610 may be in a range of about 56% to about 62%. As an example, a maximum transmittance of the transmission spectrum of the first color filter 610 may be about 59%.

FIG. 9 is a schematic graph showing a transmission spectrum of the first to third color filters according to an embodiment.

Referring to FIG. 9, the second color filter 620 is a red color filter corresponding to the second sub-pixel PX2. Similar to the first color filter 610, the second color filter 620 may have a transmission spectrum optimized for the spectrum of light emitted from the second light-emitting diode LED2 and the second quantum-dot layer 520. In addition, the third color filter 630 is a blue color filter corresponding to the third sub-pixel PX3. The third color filter 630 may have a transmission spectrum optimized for the spectrum of light emitted from the third light-emitting diode LED3 and passing through the transmission layer 530.

In an embodiment, a peak wavelength of the transmission spectrum of the second color filter 620 may be about 585 nm to about 600 nm with a transmittance of about 10%. As an example, a peak wavelength of the transmission spectrum of the second color filter 620 may be about 599 nm.

In addition, in an embodiment, a maximum transmittance of the transmission spectrum of the second color filter 620 may be in a range of about 60% to about 70%.

In an embodiment, a peak wavelength of the transmission spectrum of the third color filter 630 may be in a range of about 420 nm to about 480 nm. As an example, a peak wavelength of the transmission spectrum of the third color filter 630 may be about 450 nm.

In addition, in an embodiment, an FWHM of the transmission spectrum of the third color filter 630 may be in a range of about 87 nm to about 93 nm. As an example, an FWHM of the transmission spectrum of the third color filter 630 may be about 89 nm.

In an embodiment, a maximum transmittance of the transmission spectrum of the third color filter 630 may be in a range of about 65% to about 71%. As an example, a maximum transmittance of the transmission spectrum of the third color filter 630 may be about 68%.

In an embodiment, the display apparatus 1 may have a color reproduction rate of 89% or more according to the BT2020 standard. In an embodiment, the display apparatus 1 may have a color reproduction rate of 90% or more according to the BT2020 standard. In an embodiment, the display apparatus 1 may have a color reproduction rate of 91% or more according to the BT2020 standard.

Here, the “BT2020” is a standard proposed by the International Telecommunication Union (ITU), and defines the color gamut. The “BT2020 standard color reproduction rate” denotes a coincidence rate of a color gamut of the display apparatus with respect to a color gamut according to the BT2020 standard in CIE color coordinates. For example, the “BT2020 standard color reproduction rate” corresponds to a ratio of the area of a matching portion to the total area of a reference color gamut.

In an embodiment, the display apparatus 1 may have a Specular Component Included (SCI) reference reflectance of less than 1.3. In an embodiment, the display apparatus 1 may have an SCI reference reflectance of less than 1.2. In an embodiment, the display apparatus 1 may have an SCI reference reflectance of less than 1.1.

Here, the “SCI reference reflectance” is a reflectance measured by an SCI method, and refers to reflectance including both incident and regularly reflected light and diffusely reflected light.

The first color filter 610 having transmission spectrum characteristics according to an embodiment may include a first pigment that is green, and a second pigment that is yellow. For example, the first color filter 610 may be manufactured by mixing green pigment and yellow pigment.

In an embodiment, the first pigment may include at least one selected from, for example, C.I. Pigment Green 7, C.I. Pigment Green 36, C.I. Pigment Green 58, and C.I. Pigment Green 69.

In an embodiment, the second pigment may include at least one selected from C.I. Pigment Yellow 129, C.I. Pigment Yellow 138, C.I. Pigment Yellow 139, C.I. Pigment Yellow 185 and C.I. Pigment Yellow 231.

A peak wavelength and an FWHM of a transmission spectrum of the first filter 610 may be changed according to a mixing ratio of the first pigment to the second pigment. In an embodiment, a weight ratio of the first pigment to the second pigment may be about 86:14 to about 94:6. As an example, a weight ratio of the first pigment to the second pigment may be about 90:10. In the embodiment in which a weight ratio of the first pigment to the second pigment does not satisfy the above range, the reflectance of the display apparatus 1 may increase and a color reproduction rate and a light transmission efficiency of the display apparatus 1 may be reduced.

In an embodiment, the thickness of the first color filter 610 may be in a range of about 2 μm to about 4 μm. As an example, the thickness of the first color filter 610 may be about 3.2 μm.

In an embodiment, content of a total pigment included in the first color filter 610 may be about 4 wt % to about 12 wt % based on solid content. In an embodiment, content of a total pigment included in the first color filter 610 may be about 5.4 wt % to about 10.8 wt % based on solid content. As an example, content of a total pigment included in the first color filter 610 may be about 7.2% based on solid content.

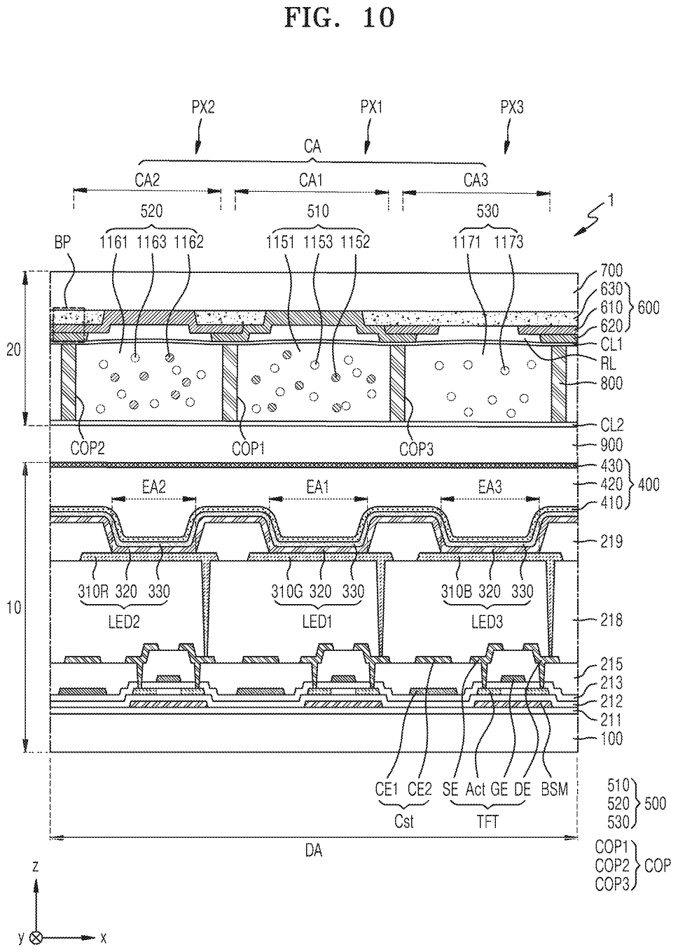

FIG. 10 is a schematic cross-sectional view of the display apparatus 1 according to an embodiment. The display apparatus 1 may include the first color filter 610, the second color filter 620, and the third color filter 630 each having the transmission spectrum described above with reference to FIGS. 5 to 9.

Referring to FIG. 10, the display apparatus 1 may include a first sub-pixel PX1, a second sub-pixel PX2, and a third sub-pixel PX3. The first sub-pixel PX1 may implement green light Lg, the second sub-pixel PX2 may implement red light Lr, and the third sub-pixel PX3 may implement blue light Lb.

In an embodiment, the display apparatus 1 may include a display panel 10 and a color-converting panel 20. The display panel 10 may include a lower substrate 100 and a display element on the lower substrate 100. In an embodiment, the display panel 10 may include the first light-emitting diode LED1, the second light-emitting diode LED2, and the third light-emitting diode LED3 each disposed over the lower substrate 100. The first light-emitting diode LED1, the second light-emitting diode LED2, and the third light-emitting diode LED3 may each include an emission layer 320.

Hereinafter, a stack structure of the display panel 10 is described in more detail.

The lower substrate 100 may include a glass material, a ceramic material, metal, or a flexible or bendable material. In the embodiment in which the lower substrate 100 is flexible or bendable, the lower substrate 100 may include a polymer resin including polyethersulfone, polyacrylate, polyetherimide, polyethylene naphthalate, polyethylene terephthalate, polyphenylene sulfide, polyarylate, polyimide, polycarbonate, and/or cellulose acetate propionate. The lower substrate 100 may have a single-layered structure or a multi-layered structure of the above materials, and may further include an inorganic layer in the embodiment of the multi-layered structure. In an embodiment, the lower substrate 100 may have a structure of an organic material/an inorganic material/an organic material.

A barrier layer may be further disposed between the lower substrate 100 and a first buffer layer 211. The barrier layer may prevent or reduce the penetration of impurities from the lower substrate 100 and/or the like to a semiconductor layer Act.

The barrier layer may include an inorganic material, an organic material, or an organic/inorganic composite material, and include a single layer or a multi-layer including an inorganic material and/or an organic material, the inorganic material including oxide or nitride.

A bias electrode BSM may be on the first buffer layer 211 to correspond to a thin-film transistor TFT. In an embodiment, a voltage may be applied to the bias electrode BSM. In addition, the bias electrode BSM may prevent (reduce) external light reaching the semiconductor layer Act. Accordingly, the characteristics of the thin-film transistor TFT may be stabilized. In addition, the bias electrode BSM may be omitted depending on the embodiment.

The semiconductor layer Act may be on a second buffer layer 212. The semiconductor layer Act may include amorphous silicon or polycrystalline silicon. In another embodiment, the semiconductor layer Act may include an oxide of at least one selected from indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In another embodiment, the semiconductor layer Act may include Zn-oxide-based material and include Zn-oxide, In—Zn oxide, and/or Ga—In—Zn oxide. In another embodiment, the semiconductor layer Act may include In—Ga—Zn—O (IGZO), In—Sn—Zn—O (ITZO), and/or In—Ga—Sn—Zn—O (IGTZO) semiconductor containing metal such as indium (In), gallium (Ga), and/or stannum (Sn) in ZnO. The semiconductor layer Act may include a channel region, a drain region, and a source region, the drain region and the source region being on two opposite sides of the channel region. The semiconductor layer Act may include a single layer or a multi-layer.

A gate electrode GE may be arranged over the semiconductor layer Act with a gate insulating layer 213 therebetween. The gate electrode GE may overlap at least a portion of the semiconductor layer Act. The gate electrode GE may include at least one of molybdenum (Mo), aluminum (Al), copper (Cu), titanium (Ti), and/or the like and include a single layer or a multi-layer. As an example, the gate electrode GE may be a single Mo layer. A first electrode CE1 of the storage capacitor Cst may be on the same layer as the gate electrode GE. The first electrode CE1 may include the same material as that of the gate electrode GE.

The gate electrode GE of the thin-film transistor TFT is disposed separate from the first electrode CE1 of the storage capacitor Cst, and the storage capacitor Cst may overlap the thin-film transistor TFT. In this embodiment, the gate electrode GE of the thin-film transistor TFT may serve as the first electrode CE1 of the storage capacitor Cst.

An interlayer insulating layer 215 may be provided to cover the gate electrode GE and the first electrode CE1 of the storage capacitor Cst. The interlayer insulating layer 215 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ).

A second electrode CE2 of the storage capacitor Cst, a source electrode SE, and a drain electrode DE may be on the interlayer insulating layer 215.

The second electrode CE2 of the storage capacitor Cst, the source electrode SE, and the drain electrode DE may each include a conductive material including molybdenum (Mo), aluminum (Al), copper (Cu), titanium (Ti), and/or the like, and include a multi-layer or a single layer including the above materials. As an example, the second electrode CE2, the source electrode SE, and the drain electrode DE may each have a multi-layered structure of Ti/Al/Ti. The source electrode SE and the drain electrode DE may be connected to the source region and the drain region of the semiconductor layer Act through contact holes, respectively.

The second electrode CE2 of the storage capacitor Cst may overlap the first electrode CE1 with the interlayer insulating layer 215 therebetween and constitute the storage capacitor Cst. In this embodiment, the interlayer insulating layer 215 may serve as a dielectric layer of the storage capacitor Cst.

A planarization layer 218 may be on the second electrode CE2 of the storage capacitor Cst, the source electrode SE, and the drain electrode DE. The planarization layer 218 may include a single layer or a multi-layer including an organic material and provide a flat upper surface. The planarization layer 218 may include a general-purpose polymer such as benzocyclobutene (BCB), polyimide, hexamethyldisiloxane (HMDSO), polymethylmethacrylate (PMMA) and/or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or one or more blends thereof.

The display element may be on the planarization layer 218. In an embodiment, the first light-emitting diode LED1, the second light-emitting diode LED2, and the third light-emitting diode LED3 may each be disposed on the planarization layer 218. The first light-emitting diode LED1, the second light-emitting diode LED2, and the third light-emitting diode LED3 may include a first sub-pixel electrode 310G, a second sub-pixel electrode 310R, and a third sub-pixel electrode 310B, respectively. In an embodiment, the first light-emitting diode LED1, the second light-emitting diode LED2, and the third light-emitting diode LED3 may include the emission layer 320 and an opposite electrode 330 in common.

The first sub-pixel electrode 310G, the second sub-pixel electrode 310R, and the third sub-pixel electrode 310B may each include a (semi) light-transmissive electrode or a reflective electrode. In an embodiment, the first sub-pixel electrode 310G, the second sub-pixel electrode 310R, and the third sub-pixel electrode 310B may each include a reflective layer and a transparent or semi-transparent electrode layer on the reflective layer, wherein the reflective layer includes Ag, Mg, Al, Pt, Pd, Au, Ni, Nd, Ir, Cr, or a compound thereof. The transparent or semi-transparent electrode layer may include at least one selected indium tin oxide (ITO), indium zinc oxide (IZO), zinc oxide (ZnO), indium oxide (In₂O₃), indium gallium oxide (IGO), and aluminum zinc oxide (AZO). In an embodiment, the first sub-pixel electrode 310G, the second sub-pixel electrode 310R, and the third sub-pixel electrode 310B may each include ITO/Ag/ITO.

A first bank layer 219 may be on the planarization layer 218. The first bank layer 219 may include openings respectively exposing the central portions of the first sub-pixel electrode 310G, the second sub-pixel electrode 310R, and the third sub-pixel electrode 3108. The first bank layer 219 may cover the edges of the first sub-pixel electrode 310G, the second sub-pixel electrode 310R, and the third sub-pixel electrode 310B. The first bank layer 219 may prevent (reduce) arcs and/or the like from occurring at the edges of the first sub-pixel electrode 310G, the second sub-pixel electrode 310R, and the third sub-pixel electrode 310B by increasing a distance between the edges of the first sub-pixel electrode 310G, the second sub-pixel electrode 310R, and the third sub-pixel electrode 310B and the opposite electrode 330 over the first sub-pixel electrode 310G, the second sub-pixel electrode 310R, and the third sub-pixel electrode 310B.

The first bank layer 219 may include an organic insulating material such as polyimide, an acrylic resin, benzocyclobutene, a phenolic resin, and/or the like and be formed by using spin coating and/or the like.

The emission layer 320 of the first light-emitting diode LED1, the second light-emitting diode LED2, and the third light-emitting diode LED3 may include a fluorescent or phosphorous material that emits green, red, blue, or white light. The emission layer 320 may include a polymer organic material and/or a low molecular weight organic material. Functional layers may be selectively further arranged under and on the emission layer 320, the functional layers including a hole transport layer (HTL), a hole injection layer (HIL), an electron transport layer (ETL), and an electron injection layer (EIL). The emission layer 320 is provided as one body over the first sub-pixel electrode 310G, the second sub-pixel electrode 310R, and the third sub-pixel electrode 310B, the embodiment is not limited thereto. The emission layer 320 may correspond to each of the first sub-pixel electrode 310G, the second sub-pixel electrode 310R, and the third sub-pixel electrode 3108. However, various suitable modifications may be made.

Though the emission layer 320 may include a layer having one body over the first sub-pixel electrode 310G, the second sub-pixel electrode 310R, and the third sub-pixel electrode 310B, the emission layer 320 may include a layer patterned to correspond to each of the first sub-pixel electrode 310G, the second sub-pixel electrode 310R, and the third sub-pixel electrode 310B when needed. In any embodiment, the emission layer 320 may be a first-color emission layer. The first-color emission layer may be one body over the first sub-pixel electrode 310G, the second sub-pixel electrode 310R, and the third sub-pixel electrode 310B, or may be patterned to correspond to each of the first sub-pixel electrode 310G, the second sub-pixel electrode 310R, and the third sub-pixel electrode 3106 when needed. The first-color emission layer may emit light in a first wavelength band and may emit, for example, blue light.

The opposite electrode 330 may be on the emission layer 320 to correspond to the first sub-pixel electrode 310G, the second sub-pixel electrode 310R, and the third sub-pixel electrode 310B. The opposite electrode 330 may be provided as one body over a plurality of organic light-emitting elements. In an embodiment, the opposite electrode 330 may be a transparent or semi-transparent electrode and may include a metal thin film including Li, Ca, LiF/Ca, LiF/Al, Al, Ag, Mg, or a compound thereof and having a small work function. In addition, a transparent conductive oxide (TCO) such as ITO, IZO, ZnO, or In₂O₃ may be further disposed on the metal thin film.

In an embodiment, first light may be generated from a first emission area EA1 of the first light-emitting diode LED1 and emitted to the outside. In an embodiment, the first emission area EA1 may be defined by a portion of the first sub-pixel electrode 310G exposed by the opening of the first bank layer 219. Second light may be generated from a second emission area EA2 of the second light-emitting diode LED2 and emitted to the outside. In an embodiment, the second emission area EA2 may be defined by a portion of the second sub-pixel electrode 310R exposed by the opening of the first bank layer 219. Third light may be generated from a third emission area EA3 of the third light-emitting diode LED3 and emitted to the outside. In an embodiment, the third emission area EA3 may be defined by a portion of the third sub-pixel electrode 310B exposed by the opening of the first bank layer 219.

The first emission area EA1, the second emission area EA2, and the third emission area EA3 may be apart from one another. A region of the display area DA that is not the first emission area EA1, the second emission area EA2, and the third emission area EA3 may be a non-emission area. The first emission area EA1, the second emission area EA2, and the third emission area EA3 may be discriminated from each other by the non-emission area.

A spacer for preventing (reducing) mask chopping may be further disposed on the first bank layer 219. In an embodiment, the spacer may be formed as one body with the first bank layer 219. As an example, the spacer and the first bank layer 219 may be concurrently (e.g., simultaneously) formed during substantially the same process that uses a half-tone mask process.

Because the first light-emitting diode LED1, the second light-emitting diode LED2, and the third light-emitting diode LED3 may be damaged by external moisture or oxygen, the first light-emitting diode LED1, the second-emitting diode LED2, and the third light-emitting diode LED3 may be covered and protected by the encapsulation layer 400. The encapsulation layer 400 may cover the display area DA and extend to the outside of the display area DA. The encapsulation layer 400 may include at least one organic encapsulation layer and at least one inorganic encapsulation layer. As an example, the encapsulation layer 400 includes a first inorganic encapsulation layer 410, an organic encapsulation layer 420, and a second inorganic encapsulation layer 430.

Because the first inorganic encapsulation layer 410 is formed along a structure thereunder, an upper surface thereof may not be flat. The organic encapsulation layer 420 may cover the first inorganic encapsulation layer 410 and, unlike the first inorganic encapsulation layer 410, an upper surface of the organic encapsulation layer 420 may be approximately flat.

The first inorganic encapsulation layer 410 and the second inorganic encapsulation layer 430 may each include at least one inorganic material selected from among aluminum oxide (Al₂O₃), titanium oxide (TiO₂), tantalum oxide (Ta₂O₅), hafnium oxide (HfO₂), zinc oxide (ZnOₓ), silicon oxide (SiOₓ), and silicon nitride (SiNₓ), silicon oxynitride (SiON). The organic encapsulation layer 420 may include a polymer-based material. The polymer-based material may include an acryl-based resin, an epoxy-based resin, polyimide, and/or polyethylene. In an embodiment, the organic encapsulation layer 420 may include acrylate.

Even when cracks occur inside the encapsulation layer 400, the encapsulation layer 400 may prevent or reduce connection of cracks between the first inorganic encapsulation layer 410 and the organic encapsulation layer 420 or between the organic encapsulation layer 420 and the second inorganic encapsulation layer 430 through the above multi-layered structure. Through this, a path may be prevented or reduced, wherein external moisture, oxygen, and/or the like penetrates into the display area DA.

Other layers such as a capping layer may be between the first inorganic encapsulation layer 410 and the opposite electrode 330 when needed.

The color-converting panel 20 may include an upper substrate 700, a color filter layer 600, a refractive layer RL, a first capping layer CL1, a second bank layer 800, a functional layer 500, and/or a second capping layer CL2. The upper substrate 700 may be over the lower substrate 100 with the display element therebetween. The upper substrate 700 may be over the first light-emitting diode LED1, the second-emitting diode LED2, and the third light-emitting diode LED3.

The upper substrate 700 may include glass, metal, and/or a polymer resin. In the embodiment in which the upper substrate 700 is flexible or bendable, the upper substrate 700 may include, for example, a polymer resin including polyethersulphone, polyacrylate, polyetherimide, polyethylene naphthalate, polyethylene terephthalate, polyphenylene sulfide, polyarylate, polyimide, polycarbonate, and/or cellulose acetate propionate. In an embodiment, the upper substrate 700 may have a multi-layered structure including two layers and a barrier layer between the two layers, wherein the two layers include the above polymer resins, and the barrier layer includes an inorganic material such as silicon oxide (SiOₓ), silicon nitride (SiNₓ), silicon oxynitride (SiON), and/or the like.

The color filter layer 600 may be on the lower surface of the upper substrate 700 in a direction from the upper substrate 700 to the lower substrate 100. The color filter layer 600 may include the first color filter 610, the second color filter 620, and the third color filter 630 each having the transmission spectrum described above with reference to FIGS. 5 to 9. The first color filter 610 may be arranged in a first central area CA1. The second color filter 620 may be arranged in a second central area CA2. The third color filter 630 may be arranged in a third central area CA3.

The color filter layer 600 may reduce external light reflection of the display apparatus 1. As an example, when external light reaches the first color filter 610, only light in a wavelength band set in advance may pass through the first color filter 610 as described above, and light in the other wavelengths may be absorbed by the first color filter 610. Accordingly, among external light incident to the display apparatus 1, only light in the wavelength band set in advance may pass through the first color filter 610, and a portion of the light that passes through the first color filter 610 may be reflected by the opposite electrode 330 and/or the first sub-pixel electrode 310G thereunder and emitted to the outside. Because, among external light incident to where the first sub-pixel PX1 is located, only a portion of the external light is reflected, external light reflection may be reduced. This description is applicable to the second color filter 620 and the third color filter 630.

The first color filter 610, the second color filter 620, and the third color filter 630 may overlap each other. The first color filter 610, the second color filter 620, and the third color filter 630 may overlap each other between one of central areas CA and another of the central areas CA. As an example, the first color filter 610, the second color filter 620, and the third color filter 630 may overlap each other between the first central area CA1 and the second central area CA2. In this embodiment, the third color filter 630 may be arranged between the first central area CA1 and the second central area CA2. The first color filter 610 may extend from the first central area CA1 to overlap the third color filter 630. The second color filter 620 may extend from the second central area CA2 to overlap the third color filter 630.

As described above, the first color filter 610, the second color filter 620, and the third color filter 630 may overlap each other to define a light-blocking part BP. Accordingly, the color filter layer 600 may prevent or reduce color mixing even without a separate light-blocking member.

The refractive layer RL may be arranged in the central area CA. The refractive layer RL may be arranged in the first central area CA1, the second central area CA2, and the third central area CA3. The refractive layer RL may include an organic material. In an embodiment, the refractive index of the refractive layer RL may be less than the refractive index of the first capping layer CL1. In an embodiment, the refractive index of the refractive layer RL may be less than the refractive index of the color filter layer 600. Accordingly, the refractive layer RL may condense light.

The first capping layer CL1 may be on the refractive layer RL and the color filter layer 600. In an embodiment, the first capping layer CL1 may be between the color filter layer 600 and the functional layer 500. The first capping layer CL1 may protect the refractive layer RL and the color filter layer 600. The first capping layer CL1 may prevent or reduce impurities, such as external moisture and/or air, penetrating to damage or contaminate the refractive layer RL and/or the color filter layer 600. The first capping layer CL1 may include an inorganic material.

The second bank 800 may be on the first capping layer CL1. The second bank 800 may include an organic material. Depending on the embodiment, the second bank layer 800 may include a light-blocking material to serve as a light-blocking layer. The light-blocking material may include at least one selected from, for example, black pigment, black dye, black particles, and metal particles.

Central openings COP may be defined in the second bank layer 800. The central opening COP may overlap the central area CA. The first central opening COP1 may overlap the first central opening CA1. A second central opening COP2 may overlap the second central area CA2. A third central opening COP3 may overlap the third central area CA3.

The functional layer 500 may fill the central opening COP. In an embodiment, the functional layer 500 may include at least one selected from quantum dots and scatterers (light scatterers). In an embodiment, the functional layer 500 may include the first quantum-dot layer 510, the second quantum-dot layer 520, and the transmission layer 530.

The first quantum-dot layer 510 may overlap the first central area CA1. The first quantum-dot layer 510 may fill the first central opening COP1. The first quantum-dot layer 510 may overlap the first emission area EA1. The first sub-pixel PX1 may include the first light-emitting diode LED1 and the first quantum-dot layer 510.

The first quantum-dot layer 510 may convert light in a first wavelength band generated from the emission layer 320 on the first sub-pixel electrode 310G into light in a second wavelength band. As an example, the first quantum-dot layer 510 may convert blue light to green light.

In an embodiment, the first quantum-dot layer 510 may include the first photosensitive polymer 1151, the first quantum dots 1152 dispersed in the first photosensitive polymer 1151, and the first scattering particles 1153.

The second quantum-dot layer 520 may overlap the second central area CA2. The second quantum-dot layer 520 may fill the second central opening COP2. The second quantum-dot layer 520 may overlap the second emission area EA2. The second sub-pixel PX2 may include the second light-emitting diode LED2 and the second quantum-dot layer 520.

The second quantum-dot layer 520 may convert light in a first wavelength band generated from the emission layer 320 on the second sub-pixel electrode 310R into light in a third wavelength band. As an example, the second quantum-dot layer 520 may convert blue light to red light. In an embodiment, the second quantum-dot layer 520 may include the second photosensitive polymer 1161, the second quantum dots 1162 dispersed in the second photosensitive polymer 1161, and the second scattering particles 1163.

The transmission layer 530 may overlap the third central area CA3. The transmission layer 530 may fill the third central opening COP3. The transmission layer 530 may overlap the third emission area EA3. The third sub-pixel PX3 may include the third light-emitting diode LED3 and the transmission layer 530.

The transmission layer 530 may emit light generated from the emission layer 320 on the third sub-pixel electrode 3106 to the outside without wavelength conversion. As an example, the transmission layer 530 may transmit blue light Lb without conversion.

The transmission layer 530 may include, for example, the third photosensitive polymer 1171 in which third scattering particles 1173 are dispersed. In an embodiment, the transmission layer 530 may not include (e.g., may exclude) quantum dots.

At least one selected from the first quantum dots 1152 and the second quantum dots 1162 may include a semiconductor material such as cadmium sulfide (CdS), cadmium telluride (CdTe), zinc sulfide (ZnS), indium phosphide (InP) and/or the like. The size of the quantum dot may be several nanometers, and the wavelength of light after conversion may change depending on the size of the quantum dot.

In an embodiment, the core of the quantum dot may be one of a Group II-Group VI compound, a Group III-Group V compound, a Group IV-Group VI compound, a Group IV element, a Group IV compound, and one or more combinations thereof.

A group II-VI compound may include one of a two-element compound including one of CdSe, CdTe, ZnS, ZnSe, ZnTe, ZnO, HgS, HgSe, HgTe, MgSe, MgS, and one or more mixtures thereof; a three-element compound including one of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and one or more mixtures thereof; and a four-element compound including one of HgZnTeS, CdZnSeS, CdZnSeTe, CdZnSTe, CdHgSeS, CdHgSeTe, CdHgSTe, HgZnSeS, HgZnSeTe, HgZnSTe, and one or more mixtures thereof.

A group III-V compound may include one of a two-element compound including one of GaN, GaP, GaAs, GaSb, AlN, AlP, AlAs, AlSb, InN, InP, InAs, InSb, and one or more mixtures thereof; a three-element compound including one of GaNP, GaNAs, GaNSb, GaPAs, GaPSb, AlNP, AlNAs, AlNSb, AlPAs, AlPSb, InGaP, InNP, InNAs, InNSb, InPAs, InPSb, GaNINP, and one or more mixtures thereof; and a four-element compound including one of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and one or more mixtures thereof.

A group IV-VI compound may include one of a two-element compound including one of SnS, SnSe, SnTe, PbS, PbSe, PbTe, and one or more mixtures thereof; a three-element compound including one of SnSeS, SnSeTe, SnSTe, PbSeS, PbSeTe, PbSTe, SnPbS, SnPbSe, SnPbTe, and one or more mixtures thereof; and a four-element compound including one of SnPbSSe, SnPbSeTe, SnPbSTe, and one or more mixtures thereof. A group IV element may include one of Si, Ge, and a mixture thereof. A group IV compound may include a two-element compound including one of SiC, SiGe, and a mixture thereof.

In the foregoing embodiment, the two-element compound, the three-element compound, or the four-element compound may be present inside a particle at a substantially uniform concentration, or may be divided into states with partially different concentration distributions and present in the same particle. In addition, a core-shell structure in which one quantum dot surrounds another quantum dot may be provided. An interface between the core and the shell may have a concentration gradient in which the concentration of an element existing in the shell reduces toward the center.

In an embodiment, a quantum dot may have a core-shell structure including a core and a shell, the core including a nano crystal, and the shell surrounding the core. The shell of a quantum dot may serve as a protective layer that prevents or reduces a chemical change (an adverse change) of the core to maintain a semiconductor characteristic and/or serve as a charging layer for giving an electrophoretic characteristic to the quantum dot. The shell may include a single layer or a multi-layer. An interface between the core and the shell may have a concentration gradient in which the concentration of an element existing in the shell reduces toward the center. Examples of the shell of the quantum dot include an oxide of metal or non-metal, a semiconductor compound, or a combination thereof.

As an example, though the oxide of metal or non-metal may include a two-element compound including SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a three-element compound including MgAl₂O₄, CoFe₂O₄, NiFe₂O₄, and/or CoMn₂O₄, the embodiment is not limited thereto.

In addition, though the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and/or AlSb, the embodiment is not limited thereto.

In an embodiment, a quantum dot may have an FWHM of a light emission wavelength spectrum of 45 nm or less, preferably about 40 nm or less, and more preferably about 30 nm or less. Within this range, color purity or color reproduction may be improved (increased). In addition, because light emitted from the quantum dot is emitted in all directions, a viewing angle of light may be improved (increased).

In addition, though the shape of the quantum dot is a shape generally used in the art and not for example limited, the shape of the quantum dot may include a substantially spherical shape, a pyramid shape, a multi-arm shape, or a cubic nano particle, a nano tube, a nano wire, a nano fiber, and a nano plate particle in an embodiment.

The quantum dot may be configured to adjust a color of light emitted depending on a size thereof, and thus, the quantum dot may have various suitable emission colors such as blue, red, green, and/or the like.

The first scattering particles 1153, the second scattering particles 1163, and the third scattering particles 1173 may scatter light and allow more light to be emitted. The first scattering particles 1153, the second scattering particles 1163, and the third scattering particles 1173 may increase a light-emission efficiency. At least one of the first scattering particles 1153, the second scattering particles 1163, and the third scattering particles 1173 may include any suitable material such as a metal or metal oxide for substantially uniformly scattering light. As an example, at least one selected from the first scattering particles 1153, the second scattering particles 1163, and the third scattering particles 1173 may include at least one selected from TiO₂, ZrO₂, Al₂O₃, In₂O₃, ZnO, SnO₂, Sb₂O₃, and ITO. In addition, at least one selected from the first scattering particles 1153, the second scattering particles 1163, and the third scattering particles 1173 may have a refractive index of about 1.5 or more. Accordingly, a light-emission efficiency of the functional layer 500 may improve (increase). In an embodiment, at least one selected from the first scattering particles 1153, the second scattering particles 1163, and the third scattering particles 1173 may be omitted.

The first photosensitive polymer 1151, the second photosensitive polymer 1161, and the third photosensitive polymer 1171 may include a light-transmissive organic material. As an example, at least one selected from the first photosensitive polymer 1151, the second photosensitive polymer 1161, and the third photosensitive polymer 1171 may include a polymer resin such as acryl, benzocyclobutene (BCB), and/or hexamethyldisiloxane (HMDSO).

The second capping layer CL2 may be on the second bank layer 800 and the functional layer 500. The second capping layer CL2 may protect the second bank layer 800 and the functional layer 500. The second capping layer CL2 may prevent or reduce impurities, such as external moisture and/or air, penetrating to damage or contaminate the second bank layer 800 and/or the functional layer 500. The second capping layer CL2 may include an inorganic material.

In an embodiment, a spacer may be arranged on the second capping layer CL2. The spacer may maintain an interval between the display panel 10 and the color-converting panel 20.

A filler 900 may be between display panel 10 and the color-converting panel 20. The filler 900 may perform a buffering function against external pressure and/or the like. The filler 900 may include an organic material such as methyl silicone, a phenyl silicone, polyimide, and/or the like. However, the filler 900 is not limited thereto and may include an organic sealant such as a urethane-based resin, an epoxy-based resin, and an acryl-based resin, or an inorganic sealant such as silicone.

The display apparatus according to an embodiment is designed such that a transmission spectrum of the first color filter corresponding to a green sub-pixel has an FWHM of about 45 nm to about 49 nm. Therefore, the display apparatus, which has a color reproduction rate of 90% or more measured based on the BT2020 standard and has reflectance of less than 1.1% measured by the SCI method, may be provided. However, the scope of the present disclosure is not limited by this effect.

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

The display apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope of the present disclosure as defined by the following claims and equivalents thereof.

What is claimed is:

1. A display apparatus comprising a first sub-pixel, a second sub-pixel, and a third sub-pixel respectively representing different colors, the display apparatus comprising:
an upper substrate;
a functional layer disposed over the upper substrate and comprising a first quantum-dot layer and a second quantum-dot layer, wherein the first quantum-dot layer corresponds to an emission area of the first sub-pixel, and the second quantum-dot layer corresponds to an emission area of the second sub-pixel; and
a color filter layer disposed between the upper substrate and the functional layer and comprising a first color filter, a second color filter, and a third color filter, wherein the first color filter corresponds to the first sub-pixel, the second color filter corresponds to the second sub-pixel, and the third color filter corresponds to the third sub-pixel,
wherein the first sub-pixel is a green sub-pixel, and
wherein a full width at half maximum of a transmission spectrum of the first color filter is in a range of about 45 nm to about 49 nm.

2. The display apparatus of claim 1, wherein a peak wavelength of the transmission spectrum of the first color filter is in a range of about 530 nm to about 534 nm.

3. The display apparatus of claim 1, wherein a transmittance in a wavelength band of about 380 nm to about 480 nm of the transmission spectrum of the first color filter is less than 1%.

4. The display apparatus of claim 1, wherein a transmittance in a wavelength band of about 600 nm to about 680 nm of the transmission spectrum of the first color filter is less than 1%.

5. The display apparatus of claim 1, wherein the first color filter comprises a first pigment which is green, and a second pigment which is yellow, wherein a weight ratio of the first pigment to the second pigment is about 86:14 to about 94:6.

6. The display apparatus of claim 5, wherein the first pigment comprises a green pigment, and comprises at least one selected from C.I. Pigment Green 7, C.I. Pigment Green 36, C.I. Pigment Green 58, and C.I. Pigment Green 69.

7. The display apparatus of claim 5, wherein the second pigment comprises a yellow pigment, and comprises at least one selected from C.I. Pigment Yellow 129, C.I. Pigment Yellow 138, C.I. Pigment Yellow 139, C.I. Pigment Yellow 185, and C.I. Pigment Yellow 231.

8. The display apparatus of claim 1, wherein a thickness of the first color filter is in a range of about 2 μm to about 4 μm.

9. The display apparatus of claim 1, wherein content of a total pigment included in the first color filter is about 4 wt % to about 12 wt % based on solid content.

10. The display apparatus of claim 1, wherein each of the first sub-pixel, the second sub-pixel, and the third sub-pixel includes a light-emitting diode, and
all of the light-emitting diodes are configured to emit blue light.

11. The display apparatus of claim 1, wherein a color reproduction rate according to a BT2020 standard is 90% or more.

12. A display apparatus comprising:
a lower substrate;
a first sub-pixel, a second sub-pixel, and a third sub-pixel each comprising a light-emitting diode which is over the lower substrate and configured to emit blue light;
an upper substrate over the lower substrate with the light-emitting diode therebetween;
a functional layer over a surface of the upper substrate facing the lower substrate, wherein the functional layer comprises a first quantum-dot layer, a second quantum-dot layer, and a transmission layer, wherein the first quantum-dot layer corresponds to the first sub-pixel, the second quantum-dot layer corresponds to the second sub-pixel, and the transmission layer corresponds to the third sub-pixel; and
a color filter layer disposed between the upper substrate and the functional layer and comprising a first color filter, a second color filter, and a third color filter, wherein the first color filter corresponds to the first sub-pixel, the second color filter corresponds to the second sub-pixel, and the third color filter corresponds to the third sub-pixel,
wherein the first sub-pixel is a green sub-pixel, and
wherein the first color filter comprises a first pigment which is green, and a second pigment which is yellow, and a weight ratio of the first pigment to the second pigment is about 86:14 to about 94:6.

13. The display apparatus of claim 12, wherein the first pigment comprises a green pigment, and comprises at least one selected from C.I. Pigment Green 7, C.I. Pigment Green 36, C.I. Pigment Green58, and C.I. Pigment Green 69.

14. The display apparatus of claim 12, wherein the second pigment comprises a yellow pigment, and comprises at least one selected from C.I. Pigment Yellow 129, C.I. Pigment Yellow 138, C.I. Pigment Yellow 139, C.I. Pigment Yellow 185, and C.I. Pigment Yellow 231.

15. The display apparatus of claim 12, wherein a thickness of the first color filter is in a range of about 2 μm to about 4 μm.

16. The display apparatus of claim 12, wherein content of a total pigment included in the first color filter is about 4 wt % to about 12 wt % based on solid content.

17. The display apparatus of claim 12, wherein a full width at half maximum of a transmission spectrum of the first color filter is in a range of about 45 nm to about 49 nm.

18. The display apparatus of claim 12, wherein a peak wavelength of a transmission spectrum of the first color filter is in a range of about 530 nm to about 534 nm.

19. The display apparatus of claim 12, wherein a transmittance in a wavelength band of about 380 nm to about 480 nm of a transmission spectrum of the first color filter is less than 1%.

20. The display apparatus of claim 12, wherein a transmittance in a wavelength band of about 600 nm to about 680 nm of a transmission spectrum of the first color filter is less than 1%.
